(19) United States
(12) Patent Application Publication
(10) Pub. No.: US 2013/0074930 A1
(43) Pub. Date: Mar. 28, 2013

(54) POLYMETHYL (METH)ACRYLATE MOULDINGS FOR FLUORESCENCE CONVERSION, PRODUCTION OF THESE BY THE SHEET CASTING PROCESS AND USE IN SOLAR COLLECTORS

(71) Applicants: Hans Lichtenstein, Reinheim (DE); Claudius Neumann, Rossdorf (DE)

(72) Inventors: Hans Lichtenstein, Reinheim (DE); Claudius Neumann, Rossdorf (DE)

(73) Assignee: Evonik Roehm GmbH, Darmstadt (DE)

(21) Appl. No.: 13/701,715

(22) PCT Filed: Jul. 5, 2011
(86) PCT No.: PCT/EP2011/061261

§ 371 Date: Dec. 3, 2012

(30) Foreign Application Priority Data
Jul. 30, 2010 (DE) 10 2010 038 685.5

(51) Int. Cl. G02B 5/22; H01L 31/0216

(52) U.S. Cl. CPC G02B 5/223; H01L 31/02168
USPC 136/257; 252/589

(57) ABSTRACT

The invention relates to a combination of fluorescence conversion dyes in plastics mouldings made of polymethyl (meth)acrylate, where these are used to convert natural insolation into light that can be used by the solar cells. The plastics mouldings are polymerized by the casting process

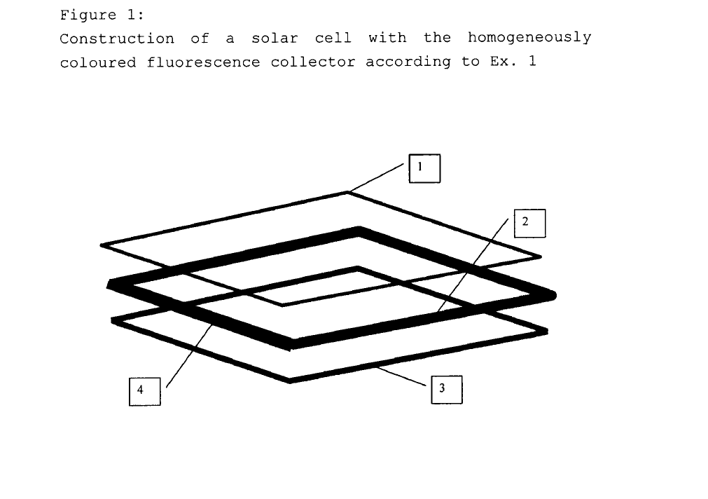

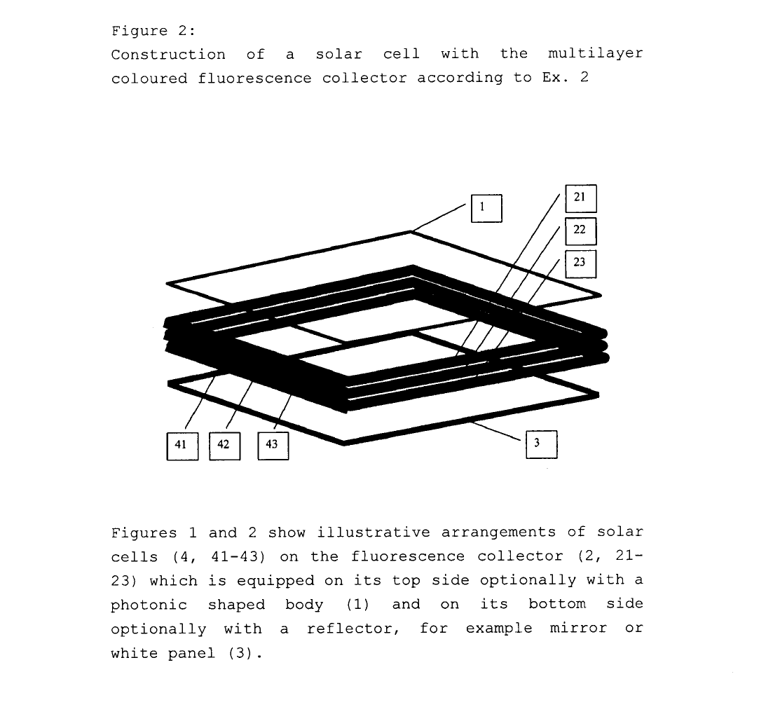

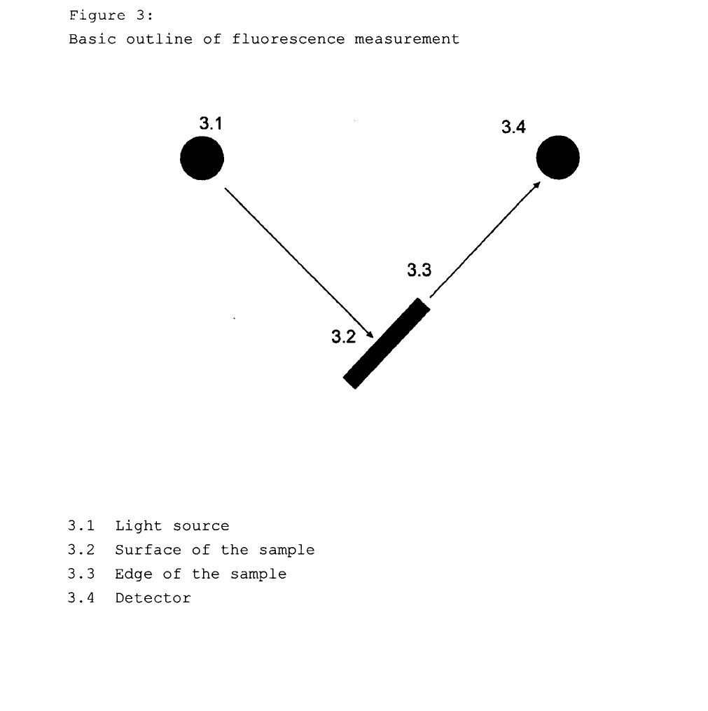

### FIELD OF THE INVENTION

The invention relates to a combination of fluorescence conversion dyes in shaped polymer bodies composed of polymethyl (meth)acrylate, which are used to convert natural solar radiation, over a particularly long period, to light usable by the solar cells. The shaped polymer bodies are polymerized in a casting process.

### STATE OF THE ART

Photovoltaic cells can convert only some of the incident sunlight to usable electrical energy; a large portion of the energy is lost in the form of heat. For example, a silicon solar cell can absorb all photons which have an energy above the band edge of 1.1 eV of crystalline silicon. This corresponds to a wavelength of <1100 nm. The excess energy of the absorbed photons is converted to heat and leads to heating of the photo cell; the efficiency of the photo cell is lowered.

The construction and the effect of fluorescence conversion solar cells is known from U.S. Pat. No. 4,110,123 (Fraunhofer) or from Appl. Phys. 14, 123 ff (1977).

WO 2007/031446 (BASF AG) describes fluorescence conversion solar cells formed from one or more glass plates or polymer slabs, which are coated with a fluorescent dye. The fluorescent dyes used are dyes based on terrylenecarboxylic acid derivatives or combinations of these dyes with other fluorescent dyes. A disadvantage here is the separate step required for coating of the glass plates with the formulation which comprises the dye.

### Concentrator Systems Comprising Lenses or Mirrors

Optical systems based on lenses or mirrors for concentrating the light onto the solar cells are known; concentration factors of up to 1000-fold are achieved. A disadvantage of the optical solutions is, however, that the entire electromagnetic spectrum of light is concentrated, such that not only the effective light is concentrated, but also the photovoltaically ineffective light. This leads to undesired thermal stress on the solar cells and to a decrease in the efficiency. In order not to allow the temperatures to become too high, the solar cells can be cooled actively or passively. Furthermore, the lenses or the lens systems have to track the position of the sun mechanically in a complex manner; in addition, they can only image the directly incident light. Diffuse light makes little contribution to energy generation, if any at all (see U.S. Pat. No. 5,489,297).

### Problem

In view of the prior art discussed above, the problem addressed was to develop concentration methods for the optical radiation of the sun, which are capable of
utilizing diffuse light and therefore not needing complex tracking mechanics,
providing light adjusted to the absorption spectrum of the solar cell used (for example Si or GaAs),
achieving a concentration comparable to optical concentrators,
being produced easily and inexpensively,
reducing the thermal stress on the solar cells and the associated loss of efficiency,
reducing the active solar cell area,
being resistant to weathering influences, and the optical properties remaining virtually unchanged in the course of operation.

### Solution

The problem detailed above is solved by use of different fluorescence conversion dyes in combination with specific UV absorbers and optionally free-radical scavengers in shaped polymer bodies, the spectra of the dyes being matched to one another such that the incident light is emitted in a controlled manner with wavelengths matched to the particular solar cell.

The solution further comprises the dissolution of the dyes or of the dye mixtures in a monomer mixture, which is then polymerized to a shaped polymer body.

The shaped polymer body may have a single-layer or multilayer structure and comprise layers which comprise identical or different dyes or dye mixtures. The individual layers may be bonded to one another in a fixed manner, for example by adhesive bonding or by polymerization. This can be accomplished, for example, by processes described in applications DE 10233684 and DE 10254276.

However, the layering can also be accomplished by loose stacking of the individual shaped polymer bodies one on top of another.

The inventive solution offers the following advantages:
the incident sunlight is converted to optimal wavelengths for silicon photovoltaic cells,
the fluorescence conversion solar cells can be produced by known processes,
the solar cells are protected from vandalism,
the conversion rates are surprisingly high,
the shaped polymer body can be matched in a simple manner to the geometric and static requirements of the solar cell,
the shaped polymer body is lighter than a comparable arrangement made from mineral glass,
the shaped polymer body can be impact-modified, such that the solar cell arrangement is protected from hail,
the shaped polymer body, compared to similar unstabilized shaped bodies, exhibits only a slight decrease or even an increase in fluorescence intensity in the course of weathering.

### The Production of the Shaped Polymer Body

### The Monomers

### The (Meth)Acrylates

A particularly preferred group of monomers is that of (meth)acrylates. The expression “(meth)acrylates” encompasses methacrylates and acrylates, and mixtures of the two.

These monomers are widely known. They include (meth)acrylates which derive from saturated alcohols, for example methyl (meth)acrylate, ethyl (meth)acrylate, propyl (meth)acrylate, isopropyl (meth)acrylate, n-butyl (meth)acrylate, tert-butyl (meth)acrylate, butoxymethyl (meth)acrylate, pentyl (meth)acrylate, hexyl (meth)acrylate, heptyl (meth)acrylate, octyl (meth)acrylate, isooctyl (meth)acrylate, isodecyl (meth)acrylate, tetrahydrofurfuryl (meth)acrylate, cyclohexyl (meth)acrylate and 2-ethylhexyl (meth)acrylate; (meth)acrylates which derive from unsaturated alcohols, for example oleyl (meth)acrylate, 2-propynyl (meth)acrylate, allyl (meth)acrylate, vinyl (meth)acrylate; aryl (meth)acrylates, for example benzyl (meth)acrylate or phenyl (meth)acrylate, where the aryl radicals may each be unsubstituted or up to tetrasubstituted; cycloalkyl (meth)acrylates, for example 3-vinylcyclohexyl (meth)acrylate, bornyl (meth)acrylate, isobornyl (meth)acrylate; hydroxyalkyl (meth)acrylates, for example 3-hydroxypropyl (meth)acrylate, 3,4-dihydroxybutyl (meth)acrylate, 2-hydroxyethyl (meth)acrylate, 2-hydroxypropyl (meth)acrylate; glycol di(meth)acrylates, for example 1,4-butanediol (meth)acrylate, (meth)acrylates of ether alcohols, for example tetrahydrofurfuryl (meth)acrylate, vinyloxyethoxyethyl (meth)acrylate; amides and nitriles of (meth)acrylic acid, for example N-(3-dimethylaminopropyl)(meth)acrylamide, N-(diethylphosphono)(meth)acrylamide, 1-methacryloylamido-2-methyl-2-propanol; sulphur-containing methacrylates, for example ethylsulphinylethyl (meth)acrylate, 4-thiocyanatobutyl (meth)acrylate, ethylsulphonylethyl (meth)acrylate, thiocyanatomethyl (meth)acrylate, methylsulphinylmethyl (meth)acrylate, bis((meth)acryloyloxyethyl) sulphide; polyfunctional (meth)acrylates, for example trimethylolpropane tri(meth)acrylate.

These monomers can be used individually or as a mixture. Particular preference is given here to mixtures which comprise methacrylates and acrylic esters.

### The Free-Radical Formers

The polymerization is generally initiated with known free-radical initiators. The preferred initiators include the azo initiators widely known in the technical field, such as AIBN and 1,1-azobiscyclo-hexanecarbonitrile, and peroxy compounds such as methyl ethyl ketone peroxide, acetylacetone peroxide, dilauryl peroxide, tert-butyl per-2-ethylhexanoate, ketone peroxide, methyl isobutyl ketone peroxide, cyclohexanone peroxide, dibenzoyl peroxide, tert-butyl peroxybenzoate, tert-butyl peroxyisopropyl carbonate, 2,5-bis(2-ethylhexanoylperoxy)-2,5-dimethylhexane, tert-butyl peroxy-2-ethylhexanoate, tert-butyl peroxy-3,5,5-trimethylhexanoate, dicumyl peroxide, 1,1-bis(tert-butylperoxy)cyclohexane, 1,1-bis(tert-butyl-peroxy)-3,3,5-trimethylcyclohexane, cumyl hydro-peroxide, tert-butyl hydroperoxide, bis(4-tert-butyl-cyclohexyl) peroxydicarbonate, mixtures of two or more of the aforementioned compounds with one another, and mixtures of the aforementioned compounds with compounds which have not been mentioned and can likewise form free radicals.

These compounds are frequently used in an amount of 0.01 to 1.0% by weight, preferably of 0.05 to 0.3% by weight, based on the weight of the monomers.

### The Impact Modifiers

Preferred impact-modified castings which can serve to prepare the polymethyl methacrylate shaped bodies contain 1% by weight to 30% by weight, preferably 2% by weight to 20% by weight, more preferably 3% by weight to 15% by weight, especially 5% by weight to 12% by weight, of an impact modifier, which constitutes an elastomer phase composed of crosslinked polymer particles.

The impact modifier can be obtained in a manner known per se by bead polymerization or by emulsion polymerization.

Preferred impact modifiers are crosslinked particles having a mean particle size in the range from 50 to 1000 nm, preferably 60 to 500 nm and more preferably 80 to 120 nm.

Such particles can be obtained, for example, by the free-radical polymerization of mixtures which contain generally at least 40% by weight and preferably 50% by weight to 70% by weight of methyl methacrylate, 20% by weight to 80% by weight and preferably 25% by weight to 35% by weight of butyl acrylate, and 0.1% by weight to 2% by weight and preferably 0.5% by weight to 1% by weight of a crosslinking monomer, for example a polyfunctional (meth)acrylate, for example allyl methacrylate, and comonomers which can be copolymerized with the aforementioned vinyl compounds.

The preferred comonomers include C₁-C₄-alkyl (meth)acrylates such as ethyl acrylate or butyl methacrylate, preferably methyl acrylate, or other vinylically polymerizable monomers, for example styrene. The mixtures for preparing the aforementioned particles may preferably comprise 0% by weight to 10% by weight and preferably 0.5% by weight to 5% by weight of comonomers.

Particularly preferred impact modifiers are polymer particles which have a two-layer core-shell structure, more preferably a three-layer core-shell structure. Such core-shell polymers are described in documents including EP-A 0 113 924, EP-A 0 522 351, EP-A 0 465 049 and EP-A 0 683 028.

One structure of particularly preferred impact modifiers based on acrylate rubber is as follows:
Core: Polymer with a methyl methacrylate content of at least 90% by weight, based on the weight of the core.
Shell 1: Polymer with a butyl acrylate content of at least 80% by weight, based on the weight of the first shell.
Shell 2: Polymer with a methyl methacrylate content of at least 90% by weight, based on the weight of the second shell.

The core and the shells may, as well as the monomers mentioned, each comprise further monomers. These have been detailed above, particularly preferred comonomers having crosslinking action.

For example, a preferred acrylate rubber modifier may have the following structure:
Core: Copolymer of methyl methacrylate (95.7% by weight), ethyl acrylate (4% by weight) and allyl methacrylate (0.3% by weight),
S1: Copolymer of butyl acrylate (81.2% by weight), styrene (17.5% by weight) and allyl methacrylate (1.3% by weight),
S2: Copolymer of methyl methacrylate (96% by weight) and ethyl acrylate (4% by weight).

The ratio of core to shell(s) of the acrylate rubber modifier may vary within wide ranges. The weight ratio of core to shell C/S is preferably within the range from 20:80 to 80:20, preferably from 30:70 to 70:30, in the case of modifiers with one shell, or the ratio of core to shell 1 to shell 2 C/S1/S2 is in the range from 10:80:10 to 40:20:40, more preferably from 20:60:20 to 30:40:30, in the case of modifiers with two shells.

The particle size of the core-shell modifiers is typically in the range from 50 to 1000 nm, preferably from 100 to 500 nm and more preferably from 150 to 450 nm, without any intention that this should impose a restriction.

In a particular embodiment, the polymethyl (meth)acrylate shaped body has a modulus of elasticity of at least 2800 N/mm², preferably at least 3300 N/mm², to ISO 527/2.

The shaped polymer body may also be formed from polycarbonate (PC), polystyrene (PS), polyamide (PA), polyester (PE), thermoplastic polyurethane (PU), polyethersulphone, polysulphones, vinyl polymers, for example polyvinyl chloride (PVC).

### Light Stabilizers

Light stabilizers shall be understood to mean UV absorbers, UV stabilizers and free-radical scavengers and mixtures of the aforementioned compounds.

The UV stabilizers (UV absorbers) present in the shaped polymer body according to the invention are
derivatives of benzophenone whose substituents, such as hydroxyl and/or alkoxy groups, are usually in the 2- and/or 4-position. These preferably include 2-hydroxy-4-n-octoxybenzophenone, 2,4-dihydroxybenzophenone, 2,2′-dihydroxy-4-methoxybenzophenone, 2,2′,4,4′-tetrahydroxybenzophenone, 2,2′-dihydroxy-4,4′-dimethoxybenzophenone, 2-hydroxy-4-methoxybenzophenone
Or
substituted benzotriazoles selected from the group consisting of 2-[2-hydroxy-3,5-di(alpha,alpha-dimethylbenzyl)phenyl]benzotriazole, 2-(2-hydroxy-3,5-di-t-butylphenyl)benzotriazole (Tinuvin 320), 2-(2-hydroxy-3,5-butyl-5-methylphenyl)-5-chlorobenzo-triazole, 2-(2-hydroxy-3,5-di-t-butylphenyl)-5-chloro-benzotriazole, 2-(2-hydroxy-3,5-di-t-amylphenyl)benzo-triazole, 2-(2-hydroxy-5-t-butylphenyl)benzotriazole, 2-(2-hydroxy-3-sec-butyl-5-t-butylphenyl)benzotriazole and 2-(2-hydroxy-5-t-octylphenyl)benzotriazole, phenol, 2,2′-methylenebis[6-(2H-benzotriazol-2-yl)-4-(1,1,3,3-tetramethylbutyl)]
or
UV absorber from the class of the 2-(2′-hydroxyphenyl)-1,3,5-triazines, especially 2-(4,6-diphenyl-1,2,5-triazin-2-oxy)-5-(hexyloxy)phenol
or
ethyl 2-cyano-3,3-diphenylacrylate
or
substituted phenyl benzoates
or
compound of the formula (I)

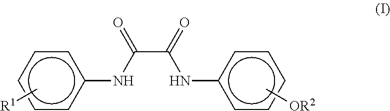

in which the R¹ and R² radicals are each independently an alkyl or cycloalkyl radical having 1 to 20 and preferably 1 to 8 carbon atoms. The aliphatic radicals are preferably linear or branched and may have substituents, for example halogen atoms.

The preferred alkyl groups include the methyl, ethyl, propyl, isopropyl, 1-butyl, 2-butyl, 2-methylpropyl, tert-butyl, pentyl, 2-methylbutyl, 1,1-dimethylpropyl, hexyl, heptyl, octyl, 1,1,3,3-tetramethylbutyl, nonyl, 1-decyl, 2-decyl, undecyl, dodecyl, pentadecyl and the eicosyl group.

The preferred cycloalkyl groups include the cyclopropyl, cyclobutyl, cyclopentyl, cyclohexyl, cycloheptyl and cyclooctyl group, which are optionally substituted by branched or unbranched alkyl groups.

Particular preference is given to using 2-ethoxy-2′-ethyloxanilide, this compound being commercially available from Clariant under the ®Sanduvor VSU trade name and from Ciba Geigy under the ®Tinuvin 312 trade name, or 2-ethoxy-5-t-butyl-2′-ethyloxanilide.

The light stabilizers or UV stabilizers may be present in the polymethacrylate compositions to be stabilized as low molecular weight compounds as specified above. However, it is also possible for UV-absorbing groups to be bonded into the matrix polymer molecules covalently after copolymerization with polymerizable UV absorption compounds, for example acryloyl, methacryloyl or allyl derivatives of benzophenone derivatives or benzo-triazole derivatives, especially the above-mentioned benzophenone or benzotriazole derivatives.

The proportion of UV stabilizers, which may also be mixtures of chemically different UV stabilizers, is generally from 0.01 to 10% by weight, in particular from 0.01 to 5% by weight, especially from 0.02 to 2% by weight, based on the (meth)acrylate copolymer.

As an example of free-radical scavengers/UV stabilizers, mention should be made here of sterically hindered amines which are known under the name HALS (Hindered Amine Light Stabilizers). They can be used for the inhibition of aging processes in coatings and plastics, in particular in polyolefin polymers (Kunststoffe, 74 (1984) 10, p. 620 to 623; Farbe+Lack, Volume 96, 9/1990, p. 689-693). The tetramethyl-piperidine group present in the HALS compounds is responsible for their stabilizing action. This compound class may be either unsubstituted or alkyl- or acyl-substituted on the piperidine nitrogen. The sterically hindered amines do not absorb in the UV region. They scavenge free radicals formed, which the UV absorbers in turn cannot do.

Examples of stabilizing HALS compounds which can also be used as mixtures are:
bis(2,2,6,6-tetramethyl-4-piperidyl) sebacate, 8-acetyl-3-dodecyl-7,7,9,9-tetramethyl-1,3,8-triaza-spiro[4.5]decane-2,5-dione, bis(2,2,6,6-tetramethyl-4-piperidyl) succinate, poly(N-(3-hydroxyethyl-2,2,6,6-tetramethyl-4-hydroxypiperidinesuccinic ester) or bis(N-methyl-2,2,6,6-tetramethyl-4-piperidyl) sebacate.

The free-radical scavengers/UV stabilizers are employed in the inventive polymer mixtures in amounts of 0.01% by weight to 15% by weight, in particular in amounts of 0.02% by weight to 10% by weight, especially in amounts of 0.02% by weight to 5% by weight, based on the (meth)acrylate copolymer.

### Oxidation Stabilizers

The oxidation stabilizers used may be sterically hindered phenols or phosphites or phosphonites. These products are sold by Ciba under the Irganox® and Irgafos® brands.

### The Casting Process

For the polymer substrates obtained by the cell casting process, for example, suitable (meth)acrylic mixtures are introduced into a mould and polymerized. Suitable (meth)acrylic mixtures generally comprise the (meth)acrylates detailed above, especially methyl methacrylate. In addition, the (meth)acrylic mixtures may comprise the copolymers detailed above and, especially to adjust the viscosity, polymers, especially poly(meth)acrylates. The weight-average molecular weight M_{w} of the polymers produced by cell casting processes is generally higher than the molecular weight of polymers which are used in moulding materials. This gives rise to a series of known advantages. In general, the weight-average molecular weight of polymers produced by cell casting processes is in the range from 500 000 to 10 000 000 g/mol, without any intention that this should impose a restriction.

In addition, light-guiding layers of the present invention can be produced by casting processes. In this case, suitable acrylic resin mixtures are introduced into a mould and polymerized.

A suitable acrylic resin comprises, for example,
1. 40% by weight to 99.999% by weight of methyl methacrylate,
2. 0% by weight to 59.999% by weight of comonomers,
3. 0% by weight to 59.999% by weight of polymers soluble in (1) or (2),
4. 0.001% by weight to 0.1% by weight of one or more fluorescent dyes, where components 1) to 4) together add up to 100% by weight.

In addition, the acrylic resin comprises the initiators needed for polymerization. Components 1 to 4 and the initiators correspond to the compounds which are also used to prepare suitable polymethyl methacrylate moulding materials.

For curing, for example, what is known as the cell casting process (see, for example, DE 25 44 245, EP-B 570 782 or EP-A 656 548) can be employed, in which the polymerization of a polymer sheet is effected between two glass plates sealed by a peripheral cord.

Preferred polymer substrates can be obtained commercially from Evonik Röhm GmbH under the trade name PLEXIGLAS® GS. The dimensions of the polymer substrates are, for example, (length×width×thickness) length 2 m, width 3 m, and the thickness may be between 1.5 mm and 200 mm, preference being given to panels with the thickness range between 2 mm and 20 mm, particular preference being given to panels in the thickness range from 3 mm to 10 mm.

### The Dyes Used

### Fluorescent Dyes

The dyes used may be dyes of the perylene, terrylene and rylene derivative types from the Lumogen® series from BASF, Rhodamine, LDS® series from Exciton, substituted pyrans (e.g. DCM), coumarins (e.g. Coumarin 30, Coumarin 1, Coumarin 102, etc.), oxazines (e.g. Nile blue, also referred to as Nile blue A), pyridines, styryl derivatives, dioxazines, naphthalimides, thiazines, stilbenes and cyanines (e.g. DODC1) from, for example, Lambdachrome® and Exciton®. The dyes of the perylene, terrylene and rylene derivative types are described in WO 2007/031446.

Complexes of the lanthanides and nanoscopic semiconductor structures, known as quantum dots, for example based on cadmium selenide, cadmium sulphide, zinc sulphide, lead selenide, lead sulphide among other compounds, are also suitable for this purpose. Production and use of quantum dots are described in US 2007/0132052, US 2007/0174939, WO 0229140, WO 2004022637, WO 2006065054 and WO 2007073467.

Complexes of the lanthanides are described in CA 20072589575, EP 0767912 and in WO 9839822, and also in Appl. Phys. Lett. 91, 051903 (2007), 23^{rd} European Photovoltaic Solar Energy Conference, Valencia, 700 (2008), Am. Chem. Soc. (2007), DOI 10.1021/ja070058e.

### The Photonic Layer

The photonic layer is arranged on the shaped polymer body, such that the sunlight must first penetrate this layer before the fluorescent dyes in the shaped polymer body can be induced to fluoresce.

Known photonic layers or wavelength-dependent mirrors are, for example, interference filters (stack filters, Rugate filters, notch filters, etc.), which may be structured as bandpass filters or edge filters. These are produced, for example, by deposition of a plurality of thin dielectric layers with different refractive indices onto a substrate (see Olaf Stenzel, “The Physics of Thin Film Optical Spectra”, Springer-Verlag and N. Kaiser, H. K. Pulker, “Optical Interference Coatings”, Springer-Verlag).

The layer thickness of the individual layer is generally less than the light wavelength.

A further option is the use of photonic crystals, which are described in the following applications (DE 10024466, DE 10204338, DE 10227071, DE 10228228, DE 102004055303, U.S. Pat. No. 6,863,847, WO 0244301, DE 10357681, DE 102004009569, DE 102004032120, WO 2006045567, DE 10245848, DE 102006017163).

These are small transparent spherical inorganic or organic bodies which are arranged in the tightest possible sphere packing. According to the size and separation of the spheres, they reflect light within a defined range and transmit the remaining light virtually completely through this layer. It is also possible to use hollow spherical structures. These are then inverse opals. The individual spherical or hollow spherical structures have the diameter of approx. ⅓ of the light wavelength to be reflected (depending on the angle of incidence of the light and the separation of the spheres).

### The Reflector

Under the shaped polymer body may optionally be arranged, to enhance the yield, an optically reflective shaped body, for example a mirror or a white film or a panel.

### The Solar Cells

The solar cell may be constructed from the customary materials, for example
Silicon solar cells
Monocrystalline silicon (c-Si), multicrystalline silicon (mc-Si), amorphous silicon (a-Si), and likewise tandem cells composed of multicrystalline and amorphous silicon
III-V semiconductor solar cells
Gallium arsenide (GaAs), gallium indium phosphide (GalnP), gallium indium arsenide (GaInAs), gallium indium arsenic phosphide (GaInAsP), gallium indium phosphide (GalnP), gallium antimonide (GaSb).
Likewise tandem cells (multiple solar cell) composed of gallium indium phosphide and gallium arsenide, of gallium indium arsenide and gallium indium arsenic phosphide, of gallium indium phosphide and gallium indium arsenide, of gallium arsenide and gallium antimonide or of gallium arsenide and germanium, or triple cells (triple solar cell) composed of gallium indium phosphide, gallium arsenide and germanium, or of gallium indium phosphide, gallium indium arsenide and gallium antimonide
II-VI semiconductor solar cells
Cadmium telluride (CdTe), cadmium sulphide (CdS)
I-III-V semiconductor solar cells
CIS cells: Copper indium diselenide (CuInSe2) or copper indium disulphide (CuInS2)
CIGS cells: Copper indium gallium diselenide (CuInGaSe2), copper gallium diselenide (CuGaSe2), copper gallium disulphide (CuGaS2)
In addition, there are also more recent developments of solar cells based on organic materials.

The table which follows shows some examples of semiconductors for solar cells. The wavelength reported corresponds to the wavelength of the light provided by the energy equal to the energy of the energy gap of the semiconductor, i.e. the semiconductor works most effectively as a solar cell with this light (the fluorescence conversion cell is adjusted to this wavelength).

| Cell material | Energy gap [eV] | Wavelength [nm] |
|---|---|---|
| Ge | 0.66 | 1879 |
| GaSb | 0.73 | 1708 |
| CuInSe2 | 1.0 | 1240 |
| Si | 1.12 | 1107 |
| GaInAs | 1.24-1.39 | 998-891 |
| GaAs | 1.42 | 873 |
| CuInS2 | 1.55 | 800 |
| CdTe | 1.56 | 795 |
| GaInP | 1.64-1.81 | 756-687 |
| CuGaSe2 | 1.68 | 738 |
| a-Si:H | 1.7 | 729 |
| CuGaS2 | 2.30 | 539 |
| CdS | 2.42 | 512 |

### Performance of the Invention

### EXAMPLES

The examples which follow serve for illustration and for better understanding of the present invention, but do not restrict it in any way.

### Description of the Production of Luminescent Solar Concentrators

### Reference Example R1

### Production of a Homogeneously Coloured Panel

1 part by weight of 2,2′-azobis(2,4-dimethylvalero-nitrile) is dissolved in 1000 parts by weight of a prepolymeric methyl methacrylate syrup (viscosity approx. 1000 cP).

Subsequently, a mixture consisting of
0.15 part by weight of Lumogen Yellow 083 (BASF)
0.16 part by weight of Lumogen Orange 240 (BASF)
0.40 part by weight of Lumogen Red 305 (BASF)
   is added.

The mixture is stirred vigorously, filled into a silicate glass cell spaced apart with 10 mm-thick cord and polymerized in a water bath at 45° C. for about 16 hours. The end polymerization is effected in a heating cabinet at 115° C. for about 4 hours.

A homogeneous red-fluorescing sheet of thickness 10 mm is obtained.

### Reference Example R2

### Device with Three Layers

### Green Cover:

1 part by weight of 2,2′-azobis(2,4-dimethylvalero-nitrile) is dissolved in 1000 parts by weight of prepolymeric methyl methacrylate syrup (viscosity approx. 1000 cP).

Subsequently,
0.15 part by weight of Lumogen Yellow 083 (BASF)
   is added.

The mixture is stirred vigorously, filled into a silicate glass cell spaced apart with 3 mm-thick cord and polymerized in a water bath at 45° C. for about 16 hours. The end polymerization is effected in a heating cabinet at 115° C. for about 4 hours.

### Red Cover:

1 part by weight of 2,2′-azobis(2,4-dimethylvalero-nitrile) is dissolved in 1000 parts by weight of prepolymeric methyl methacrylate syrup (viscosity approx. 1000 cP).

Subsequently,
0.40 part by weight of Lumogen Red 305 (BASF)
   is added.

The mixture is stirred vigorously, filled into a silicate glass cell spaced apart with 3 mm-thick cord and polymerized in a water bath at 45° C. for about 16 hours. The end polymerization is effected in a heating cabinet at 115° C. for about 4 hours.

### Inner Layer:

1 part by weight of 2,2′-azobis(2,4-dimethylvalero-nitrile) is dissolved in 1000 parts by weight of prepolymeric methyl methacrylate syrup (viscosity approx. 1000 cP).

Subsequently,
0.16 part by weight of Lumogen Orange 240 (BASF)
   is added.

The mixture is stirred vigorously, filled into a cell which is formed from the green cover and the red cover and is spaced apart with 3 mm-thick cord, and polymerized in a water bath at 45° C. for about 16 hours. The end polymerization is effected in a heating cabinet at 115° C. for about 4 hours.

A three-layer fluorescent sheet with total thickness 9 mm is obtained.

### Result

Samples in the dimensions of approx. 10×10 mm were cut from the experiments according to Examples 1 and 2, and polished on all edges. Subsequently, the fluorescence intensity was measured on an LS-55 fluorescence spectrophotometer (Perkin Elmer). For excitation, a daylight-like xenon light source was used.

The maximum intensities and the corresponding wavelengths are recorded in Table 1.

TABLE 1

| Experiment | Wavelength in nm | Rel. intensity |
|---|---|---|
| R1 | 632 | 54 |
| R2 | 577 | 487 |

The experiment according to R2 shows a significantly higher intensity.

In addition, tests were conducted in respect of the long-term stability of the fluorescent-coloured PLEXIGLAS® samples. The climate-controlled testing was effected according to standard DIN EN ISO 4892 Part 2, cycle 1^{b}. This involves exposing the specimens to filtered xenon lamp radiation under regulated ambient conditions (temperature, air humidity and wetting).

Process A - Tests with filters for global radiation (synthetic weathering)

| | | Irradiation intensity^{a} | | Black | Test | |
|---|---|---|---|---|---|---|
| | | Broadband | Narrow- | standard | chamber | Relative |
| | | (300- | band | tempera- | tempera- | air |
| Cycle | Stress | 400 nm) | (340 nm) | ture | ture | humidity |
| No. | period | W/m2 | W/(m² × nm) | ° C. | ° C. | % |
| 1 | 102 min | 60 ± 2 | 0.51 ± 0.02 | 65 ± 3 | 38 ± 3 | 50 ± 10^{b} |
| | dry | 60 ± 2 | 0.51 ± 0.02 | — | — | — |
| | 18 min | | | | | |
| | water | | | | | |
| | spraying | | | | | |

For moisture-sensitive test materials, a relative air humidity of (65±10) % is recommended.

The samples heat up to the maximum temperature of 65±3 degrees Celsius.

The samples for Examples E1 to E3 and comparative Examples C1 to C3 were produced analogously to the method of Reference Example R1.

TABLE 2
Values of relative fluorescence intensity after weathering

| | | | after |
|---|---|---|---|
| | | | 10 000 |
| Example | Dye | Stabilizer | hours |
| C1 | Lumogen Yellow 083 | —,— | −45% |
| E1 | Lumogen Yellow 083 | 0.1% by wt. of Tinuvin 320 | +13% |
| C2 | Lumogen Red 305 | —,— | −12% |
| E2 | Lumogen Red 305 | 0.1% by wt. of Tinuvin 320 | +17% |
| C3 | Lumogen Orange 240 | —,— | −19 5 |
| E3 | Lumogen Orange 240 | 0.1% by wt. of Tinuvin 320 | +10% |

The values show that the stabilized samples after 10 000 hours of weathering exhibit a distinct increase in fluorescence intensity compared to the unstabilized samples.

The samples were analysed in an LS55 fluorescence spectrophotometer (manufacturer: Perkin Elmer). This involved irradiating the surface of the sample with white artificial daylight and measuring the light signal which emerges at the edge. The measurement parameter employed was the peak height of the measurement signal.

### Reference Example R4

### Production of a Homogeneously Coloured Sheet without Light Stabilizer

### Orange Cover:

One part by weight of 2,2′-azobis(2,4-dimethylvalero-nitrile) is dissolved in 1000 parts by weight of prepolymeric methyl methacrylate syrup (viscosity approx. 1000 cP).

Subsequently,
0.5 part by weight of Lumogen Orange 240 (BASF) is added.

The mixture is stirred vigorously, filled into a silicate glass chamber spaced apart with 3 mm-thick cord, and polymerized in a water bath at 45° C. for about 16 hours. The end polymerization is effected in a heating cabinet at 115° C. for about 4 hours.

### Comparative Example C4

### Production of a Homogeneously Coloured Sheet with Unsuitable Light Stabilizer

### Comparative Example

### Orange Cover:

One part by weight of 2,2′-azobis(2,4-dimethylvalero-nitrile) is dissolved in 1000 parts by weight of prepolymeric methyl methacrylate syrup (viscosity approx. 1000 cP).

Subsequently,
1.0 part by weight of Tinuvin P and
0.5 part by weight of Lumogen Orange 240 (BASF) were added.

The mixture is stirred vigorously, filled into a silicate glass chamber spaced apart with 3 mm-thick cord, and polymerized in a water bath at 45° C. for about 16 hours. The end polymerization is effected in a heating cabinet at 115° C. for about 4 hours.

### Example E5

### Production of a Homogeneously Coloured Sheet with Suitable Light Stabilizer

### Orange Cover:

One part by weight of 2,2′-azobis(2,4-dimethylvalero-nitrile) is dissolved in 1000 parts by weight of prepolymeric methyl methacrylate syrup (viscosity approx. 1000 cP).

Subsequently,
1.0 part by weight of SANDUVOR VSU and
0.5 part by weight of Lumogen Orange 240 (BASF) were added.

The mixture is stirred vigorously, filled into a silicate glass chamber spaced apart with 3 mm-thick cord, and polymerized in a water bath at 45° C. for about 16 hours. The end polymerization is effected in a heating cabinet at 115° C. for about 4 hours.

### Example E6

### Production of a Homogeneously Coloured Sheet with Suitable Light Stabilizer

### Orange Cover:

One part by weight of 2,2′-azobis(2,4-dimethylvalero-nitrile) is dissolved in 1000 parts by weight of prepolymeric methyl methacrylate syrup (viscosity approx. 1000 cP).

Subsequently,
1.0 part by weight of Tinuvin 320 and
0.5 part by weight of Lumogen Orange 240 (BASF) were added.

The mixture is stirred vigorously, filled into a silicate glass chamber spaced apart with 3 mm-thick cord, and polymerized in a water bath at 45° C. for about 16 hours. The end polymerization is effected in a heating cabinet at 115° C. for about 4 hours.

### Result

Samples in the dimensions of approx. 10×15 mm were cut from the experiments according to Ex. 9, 10, 11 and 12, and polished on all edges. Subsequently, the fluorescence intensity was measured on an LS-55 fluorescence spectrophotometer (Perkin Elmer). For excitation, a daylight-like xenon light source was used.

The maximum intensities and the corresponding wavelengths are recorded in Table 3.

TABLE 3

| Experiment | Wavelength in nm | Rel. intensity |
|---|---|---|
| R4 | 578 | 200 |
| C4 | 582 | 74 |
| E5 | 578 | 199 |
| E6 | 578 | 205 |

The experiment according to comparative Example 4 shows a significantly higher intensity. Examples 5 and 6 show a comparable or better intensity, but, analogously to the results from Table 2, much better weathering characteristics.

### DESCRIPTION OF FIGURES

1 Photonic layer
2 Homogeneously coloured luminescent fluorescence collector
21,22,23 Multilayer coloured luminescent fluorescence collector
3 Reflector, for example mirror or white panel
4,41,42,43 Solar cells adjusted to fluorescence collector
3.1 Light source
3.2 Surface of the sample
3.3 Edge of the sample
3.4 Detector

1. A monolayer or multilayer shaped polymer body comprising:
polymethyl (meth)acrylate,
a fluorescent dye, and
a UV absorber,
wherein the UV absorber is at least one selected from the group consisting of (a), (b), (c), (d), (e), (f) and (g):
(a) a benzophenone compound whose substituents are in a 2-position, a 4-position, or both positions;
(b) a substituted benzotriazole selected from the group consisting of 2-[2-hydroxy-3,5-di(alpha, alpha-dimethylbenzyl)phenyl]benzotriazole, 2-(2-hydroxy-3,5-di-t-butylphenyl)benzotriazole, 2-(2-hydroxy-3,5-butyl-5-methylphenyl)-5-chlorobenzotriazole, 2-(2-hydroxy-3,5-di-t-butylphenyl)-5-chlorobenzotriazole, 2-(2-hydroxy-3,5-di-t-amylphenyl)benzotriazole, 2-(2-hydroxy-5-t-butylphenyl)benzotriazole, 2-(2-hydroxy-3-sec-butyl-5-t-butylphenyl)benzotriazole, 2-(2-hydroxy-5-t-octylphenyl)benzotriazole, phenol, and 2,2′-methylenebis[6-(2H-benzotriazol-2-yl)-4-(1,1,3,3-tetramethylbutyl)];
(c) a 2-(2′-hydroxy-phenyl)-1,3,5-triazine compound;
(d) ethyl 2-cyano-3,3-diphenylacrylate;
(e) a substituted phenyl benzoate;
(f) compound of formula (I) 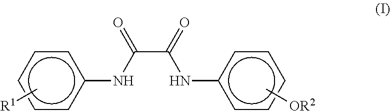
in which R¹ and R² are each independently a substituted or unsubstituted alkyl or cycloalkyl radical having 1 to 20 carbon atoms, which may be linear or branched;
(g) a UV absorbing group bonded covalently in matrix polymer molecules after copolymerization with a polymerizable UV absorption compound.

2. The shaped polymer body of claim 1,
further comprising a hindered amine light stabilizer.

3. A composite shaped polymer body, comprising a plurality of the shaped polymer bodies of claim 1,
wherein the plurality of shaped polymer bodies are adhesively bonded together.

4. A composite shaped polymer body, comprising a plurality of the shaped polymer bodies of claim 1, wherein the fluorescent dye in each of the shaped polymer bodies is the same or different.

5. The shaped polymer body of claim 1, wherein the fluorescent dye is an organic fluorescent dye.

6. The shaped polymer body of claim 1, wherein the fluorescent dye comprises a complex lanthanoid compound or a nanoscopic semiconductor structure.

7. A process for producing the shaped polymer body of claim 1, the process comprising dissolving the dye in a monomer mixture, transferring the monomer mixture to a chamber and then polymerizing the monomer mixture by increasing a temperature.

8. A device comprising the shaped polymer body of claim 1 and a solar cell.

9. The device of claim 8,
wherein
a photonic layer is disposed on the shaped polymer body.

10. The device of claim 8,
wherein
a flat reflector is disposed below the shaped polymer body.

11. The device of claim 8, wherein
a photonic layer is disposed on the shaped polymer body and a flat reflector is disposed below the shaped polymer body.

12. A solar collector comprising the shaped polymer body of claim 1.

13. A solar collector comprising the device of claim 8.

14. The shaped polymer body of claim 1, wherein the UV absorber is a benzophenone selected from the group consisting of 2-hydroxy-4-n-octoxy-benzophenone, 2,4-dihydroxybenzophenone, 2,2′-dihydroxy-4-methoxybenzophenone, 2,2′,4,4′-tetrahydroxybenzophenone, 2,2′-dihydroxy-4,4′-dimethoxybenzophenone and 2-hydroxy-4-methoxybenzophenone.

15. The shaped polymer body of claim 1, wherein the UV absorber is 2-(4,6-diphenyl-1,2,5-triazin-2-oxy)-5-(hexyloxy)phenol.

16. The shaped polymer body of claim 1, wherein the UV absorber is 2-ethoxy-2′-ethyloxanilide or 2-ethoxy-5-t-butyl-2′-ethyloxanilide.

17. The shaped polymer body of claim 2, wherein the hindered amine light stabilizer compound is selected from the group consisting of bis(2,2,6,6-tetramethyl-4-piperidyl) sebacate, 8-acetyl-3-dodecyl-7,7,9,9-tetra-methyl-1,3,8-triazaspiro[4.5]decane-2,5-dione, bis(2,2,6,6-tetramethyl-4-piperidyl) succinate, poly(N-β-hydroxyethyl-2,2,6,6-tetramethyl-4-hydroxypiperidine-succinic ester), and bis(N-methyl-2,2,6,6-tetramethyl-4-piperidyl) sebacate.

18. The shaped polymer body of claim 2, comprising 0.01 to 15 wt % of the hindered amine light stabilizer, based on a weight of the polymethyl (meth)acrylate.

19. The shaped polymer body of claim 2, comprising 0.02 to 5 wt % of the hindered amine light stabilizer, based on a weight of the polymethyl (meth)acrylate.

20. The shaped polymer body of claim 1, wherein the fluorescent dye is an organic fluorescent dye comprising at least one selected from the group consisting of a rylene compound, a perylene compound, a terrylene compound and a quaterrylene compound.
